(19) United States
(12) Patent Application Publication
(10) Pub. No.: US 2026/0304727 A1
(43) Pub. Date: Oct. 1, 2026

(54) ERROR FACTOR IDENTIFICATION DEVICE

(71) Applicant: FUJI CORPORATION, Chiryu (JP)

(72) Inventors: Anusuya NALLATHAMBI, Lafayette, IN (US); Kenji SUGIYAMA, Anjo-shi (JP)

(73) Assignee: FUJI CORPORATION, Chiryu (JP)

(21) Appl. No.: 19/481,621

(22) PCT Filed: Jun. 9, 2023
(86) PCT No.: PCT/JP2023/021457

§ 371 Date: Nov. 5, 2025

(51) Int. Cl. H05K 13/08

(52) U.S. Cl. CPC H05K 13/083

(57) ABSTRACT

An error factor identification device includes a storage section to store operation acceptability information and operation condition information; a specification section to, when an occurrence rate or an occurrence count of an error in the mounting operation exceeds a predetermined value, specify the constituent member or the mounting job data that is a factor of the error by comparing two or more of an error involvement rate of each constituent member and an error involvement rate of the mounting job data calculated based on the operation acceptability information and the operation condition information; and an estimation section configured to estimate the constituent member or the mounting job data that is the factor of the error by using a predetermined estimation logic different from the comparison of the error involvement rates.

### TECHNICAL FIELD

The present description relates to an error factor identification device that identifies a factor of an error occurring in a mounting operation of a component mounter.

### BACKGROUND ART

Techniques for mass-producing board products by performing board work on a board on which a circuit pattern is formed are well-known. A typical example of a board work machine that performs board work is a component mounter that performs a component mounting operation. In general, the component mounter includes a component supply unit such as a tape feeder that supplies components, and a component mounting unit such as a suction nozzle that picks up a component from the component supply unit and mounts the component on a board. When an error resulting from a failed mounting operation occurs, the component mounter discards the corresponding component and performs the mounting operation again using another component. For this reason, a disposal rate of components increases with an increase in errors in the mounting operation, and further, a defect rate of board products may increase.

Therefore, when errors in the mounting operation increase, a countermeasure has been implemented in which maintenance is performed on the component supply unit or the component mounting unit that is a factor of the errors and the unit is reused, or alternatively the unit is exchanged with a spare unit. In this case, by correctly identifying the unit that is a factor of the errors and performing maintenance thereon, it is possible to suppress the occurrence of errors and the disposal of components. Furthermore, it is possible to efficiently perform maintenance and reduce work costs. In addition, instead of performing maintenance on a unit after an increase in errors has occurred, a preventive measure has been carried out to suppress an increase in errors by performing regular maintenance. One technical example of identifying a factor of errors when errors in the mounting operation increase is disclosed in Patent Literature 1.

Patent Literature 1 discloses a mounting error cause estimation device including an error history storage section configured to aggregate and store an occurrence status of an error resulting from a failed mounting operation in a component mounter; a factor setting section configured to set a first factor and a second factor from among devices and data used for the mounting operation; a first determination section configured to determine whether an error occurrence status, which is obtained for each individual instance of the second factor under a condition in which an individual instance of the first factor is specified, is biased according to a difference in the second factor; a second determination section configured to determine whether the error occurrence status, which is obtained for each individual instance of the first factor under a condition in which an individual instance of the second factor is specified, is biased according to the difference in the first factor; and a cause estimation section configured to estimate a causative individual (factor) causing the error based on determination results of the first determination section and the second determination section. With this, the cause estimation device can estimate the causative individual with higher reliability than in the conventional art, based on a large number of determination results.

### CITATION LIST

### Patent Literature

Patent Literature 1: WO 2020/188774

### BRIEF SUMMARY

### Technical Problem

However, in the technical example of Patent Literature 1, when errors in the mounting operation increase, the factor of the errors cannot necessarily be identified.

In a case where the factor of the errors is not identified, there is a concern that no countermeasure is implemented and the situation is left unattended for a long time. As a result, a disposal rate of components and a defect rate of board products increase, resulting in an increase in production costs and a decrease in production efficiency. In addition, since a maintenance target is unknown, maintenance cannot be efficiently performed, and work costs required for maintenance work increase. The factor of the errors in the mounting operation is not limited to the component supply unit and the component mounting unit, and may be another constituent member of the component mounter or mounting job data involved in the mounting operation.

Therefore, an object of present description is to provide an error factor identification device capable of reducing cases where a factor of errors is not identified when errors in a mounting operation increase in a component mounter.

### Solution to Problem

The present description discloses an error factor identification device including: a storage section configured to store operation acceptability information indicating acceptability of an operation result of each of mounting operations executed multiple times in a component mounter and operation condition information indicating two or more of multiple constituent members of the component mounter and mounting job data, which are involved in each of the multiple mounting operations; a specification section configured to, when an occurrence rate or an occurrence count of an error in the mounting operation exceeds a predetermined value in at least one of the component mounter, the constituent member, and the mounting job data, specify the constituent member or the mounting job data that is a factor of the error by comparing two or more of an error involvement rate of each constituent member and an error involvement rate of the mounting job data calculated based on the operation acceptability information and the operation condition information; and an estimation section configured to estimate the constituent member or the mounting job data that is the factor of the error by using a predetermined estimation logic different from the comparison of the error involvement rates.

### Advantageous Effects

With the disclosed error factor identification device, the storage section stores the operation acceptability information and the operation condition information of each of the mounting operations executed multiple times in the component mounter. In addition, the specification section specifies the factor of the error by comparing two or more error involvement rates when the occurrence rate or the occurrence count of the error in the mounting operation exceeds the predetermined value, and the estimation section estimates the factor of the error by using an estimation logic different from that of the specification section. Here, since “specify” and “estimate” correspond to one form of “identify”, even in a case where the specification section cannot identify (specify) the factor of the error, the estimation section can identify (estimate) the factor of the error and reduce cases where the factor of the error is not identified.

### BRIEF DESCRIPTION OF DRAWINGS

FIG. 1 is a diagram including a functional block diagram of an error factor identification device of an embodiment and a plan view schematically illustrating a configuration example of a component mounter to which the error factor identification device is applied.

FIG. 2 is a diagram illustrating log data of the component mounter including operation acceptability information and operation condition information.

FIG. 3 is a diagram illustrating an example of a mounting cycle executed by the component mounter.

FIG. 4 is a diagram of an operation flow illustrating an operation of the error factor identification device of the embodiment.

FIG. 5 is a table illustrating the number of operations as a population when an occurrence rate of an error for each individual is collectively obtained for a component supply unit and a component mounting unit, each time the component mounter performs a mounting operation on a predetermined number of boards.

FIG. 6 is a table illustrating an error occurrence count, an error occurrence rate, and an error involvement rate in a first example.

FIG. 7 is a diagram of a sub-operation flow illustrating details of specification processing executed by a specification section in step S6 of the operation flow of FIG. 4.

FIG. 8 is an error factor specification diagram schematically illustrating the processing contents of the specification processing for the first example.

FIG. 9 is a table illustrating an error occurrence count, an error occurrence rate, and an error involvement rate in a second example.

FIG. 10 is an error factor specification diagram schematically illustrating the processing contents of the specification processing for the second example.

FIG. 11 is a diagram of a sub-operation flow illustrating details of estimation processing that is executed by an estimation section in step S8 of the operation flow of FIG. 4 and that uses a last execution time of maintenance.

FIG. 12 is a diagram of an operation flow of response processing executed by the error factor identification device following the operation flow of FIG. 4.

FIG. 13 is a diagram of a sub-operation flow of second estimation processing that is executed by the estimation section and that uses the error occurrence rate.

FIG. 14 is a diagram of a sub-operation flow of third estimation processing that is executed by the estimation section and that uses an execution interval of maintenance.

FIG. 15 is a diagram of a sub-operation flow of fourth estimation processing that is executed by the estimation section and that uses a next scheduled time of maintenance.

### DESCRIPTION OF EMBODIMENTS

### 1. Configuration Example of Component Mounter 1

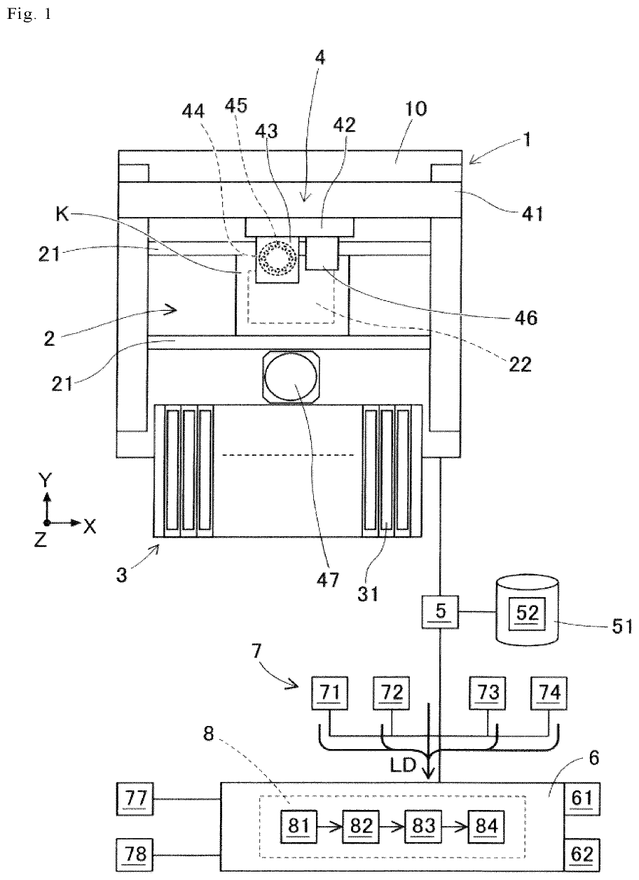

First, a configuration example of component mounter 1 to which error factor identification device 8 of an embodiment is applied will be described with reference to a plan view in FIG. 1. Component mounter 1 performs a mounting operation of mounting a component on board K. A horizontal direction from a left side toward a right side on a drawing surface in FIG. 1 is an X-axis direction in which board K is conveyed, a horizontal direction from a lower side (front side) toward an upper side (rear side) on the drawing surface is a Y-axis direction, and a vertical direction is a Z-axis direction. Component mounter 1 is configured by assembling board conveyance device 2, component supply device 3, component transfer device 4, and control device 5, and the like to base 10.

Board conveyance device 2 includes a pair of guide rails 21 serving as a conveyance path of board K. Board conveyance device 2 conveys board K loaded to a loading end (left end in FIG. 1) of guide rails 21 by a board loading device or an external conveyance device along guide rails 21 and conveys board K to a predetermined stop position. The predetermined stop position of board K is set substantially at the center of the conveyance path in a conveyance direction. Board conveyance device 2 includes positioning mechanism 22 that pushes up board K at the stop position and clamps board K between positioning mechanism 22 and guide rails 21. Component transfer device 4 executes a component mounting operation on positioned board K. After the mounting operation ends, board conveyance device 2 conveys board K from the stop position to an unloading end (right end in FIG. 1) and conveys board K out of the mounter.

Component supply device 3 is disposed at a front portion of an upper surface of base 10 in the Y-axis direction. Component supply device 3 includes multiple component supply units 31 arranged in the X axis direction. Each of component supply units 31 supplies a component in the mounting operation and corresponds to a constituent member involved in the mounting operation. In the embodiment, a tape feeder is used as component supply unit 31. The tape feeder feeds a carrier tape in which multiple components are accommodated in a row toward a supply position on a front end side. Component supply unit 31 may be a tray feeder using a tray in which components are respectively accommodated in multiple accommodation portions arranged in a grid pattern, or a stick feeder in which components are accommodated in a row inside a tubular stick.

Component transfer device 4 includes Y-axis moving body 41, X-axis moving body 42, mounting head 43, rotary tool 44, multiple component mounting units 45, board camera 46, part camera 47, and the like. Y-axis moving body 41 is formed of a member elongated in the X-axis direction, and is driven by a Y-axis drive mechanism (not illustrated) to move in the Y-axis direction. X-axis moving body 42 is mounted on Y-axis moving body 41, and is driven by an X-axis drive mechanism (not illustrated) to move in the X-axis direction. Mounting head 43 is attached to a front surface of X-axis moving body 42. Mounting head 43 is driven in two horizontal directions together with X-axis moving body 42 and moves to positions above component supply device 3 and above board K.

Rotary tool 44 is rotatably provided below mounting head 43. Rotary tool 44 is driven by an R-axis drive mechanism (not illustrated) to rotate about a vertical central axis. Rotary tool 44 holds multiple component mounting units 45 on a lower side thereof. Each of component mounting units 45 picks up a component at a supply position of component supply unit 31 and mounts the component at a mounting position on board K, and corresponds to a constituent member involved in the mounting operation. In the embodiment, a suction nozzle is used as component mounting unit 45. Mounting head 43 and rotary tool 44 hold multiple suction nozzles and move between component supply unit 31 and board K, and correspond to a constituent member involved in the mounting operation.

In the example illustrated in FIG. 1, rotary tool 44 has 12 suction nozzles (component mounting units 45) at equal distances from the vertical central axis. The suction nozzle is driven by a lifting and lowering drive mechanism (not illustrated) to be lifted and lowered, and is driven by a Q-axis drive mechanism (not illustrated) to rotate about a vertical axis. The suction nozzle is further selectively supplied with negative pressure air and positive pressure air from an air supply mechanism. Accordingly, the suction nozzle performs a mounting operation of picking up the component from component supply unit 31 and mounting the component on board K. Multiple mounting heads 43, multiple rotary tools 44, and multiple component mounting units 45 are prepared, and are automatically exchanged or manually exchanged as necessary. Mounting head 43 may be configured without rotary tool 44 and with multiple suction nozzles 45 arranged in a row or in a grid pattern. Component mounting unit 45 is not limited to the suction nozzle, and may be a chuck that grips and picks up a component.

Board camera 46 is provided facing downward on X-axis moving body 42 side by side with mounting head 43. Board camera 46 images a fiducial mark attached to board K from above. Acquired image data is subjected to image processing, so that the stop position of board K is accurately obtained. Part camera 47 is provided facing upward on base 10 between board conveyance device 2 and component supply device 3. Part camera 47 images the component picked up by component mounting unit 45 from below while mounting head 43 moves from component supply device 3 to board K. The acquired image data is subjected to image processing to determine whether the type of the component is correct or incorrect, and further, the position and orientation of the component with respect to component mounting unit 45 are detected and reflected in the mounting operation. Part camera 47 corresponds to a constituent member involved in the mounting operation. Examples of board camera 46 and part camera 47 include a digital imaging device including an imaging element such as a charge-coupled device (CCD) or a complementary metal-oxide semiconductor (CMOS).

Component transfer device 4 advances the mounting operation by repeating a mounting cycle. Describing the mounting cycle in detail, component transfer device 4 first moves mounting head 43 to component supply unit 31, and picks up the components using multiple component mounting units 45. Next, component transfer device 4 moves mounting head 43 to a position above part camera 47. Subsequently, part camera 47 captures images of component holding states of multiple component mounting units 45. Next, component transfer device 4 moves mounting head 43 to board K and mounts multiple components thereon. Next, component transfer device 4 moves mounting head 43 to component supply unit 31 again, and thus one mounting cycle is completed.

Control device 5 is assembled on base 10, and its position is not limited. Control device 5 is configured as a computer device that has CPU and that operates on software. Control device 5 may be configured such that multiple CPUs are distributed inside the device and are communicably connected. Control device 5 includes storage device 51 that stores various types of information. Control device 5 is communicably connected to line management device 6. Control device 5 receives mounting job data 52 transferred from line management device 6 and stores mounting job data 52 in storage device 51. Mounting job data 52 is data used for the mounting operation and is created for each type of board K (board product).

Mounting job data 52 includes board data related to the shape and the like of board K and component data related to the shape and the like of a component to be mounted on board K. Here, there are multiple pieces of component data that differ depending on the type and size of the component. Each of the multiple pieces of component data included in mounting job data 52 may be a factor of an error in the mounting operation. This point is similar to a case where each of multiple component supply units 31 constituting component supply device 3 may be a factor of an error, and a case where each of multiple component mounting units 45 held by mounting head 43 may be a factor of an error.

In addition, mounting job data 52 includes coordinate data of the supply position of component supply unit 31 and coordinate data of the mounting position on board K on which the component is mounted. Further, mounting job data 52 includes data related to the type and arrangement position of component supply unit 31 and component mounting unit 45 to be used, detailed procedure data of the mounting operation, and the like. Control device 5 controls board conveyance device 2, component supply device 3, and component transfer device 4 based on mounting job data 52, thereby repeating the mounting cycle and advancing the mounting operation.

### 2. Line Management Device 6 and Log Data LD

Next, line management device 6 that manages component mounter 1 and log data LD in which an operation history of component mounter 1 is recorded will be described. Line management device 6 manages board production line 7 in which multiple board work machines including component mounter 1 are arranged. Line management device 6 is configured using a computer device. Line management device 6 includes input device 61 such as a keyboard or a touch panel that receives an instruction, a selection operation, or the like from a worker or the like. Further, line management device 6 includes display device 62 such as a liquid crystal display that displays various types of information to the worker or the like.

Line management device 6 is communicably connected to feeder maintenance device 77 and nozzle maintenance device 78. Feeder maintenance device 77 receives component supply unit 31 (tape feeder) and performs maintenance on component supply unit 31. Line management device 6 can acquire an execution history of maintenance performed on component supply unit 31 by feeder maintenance device 77. Further, when regular maintenance of component supply unit 31 is performed, line management device 6 can acquire a maintenance execution interval and a future execution plan from feeder maintenance device 77.

Meanwhile, nozzle maintenance device 78 receives component mounting unit 45 (suction nozzle) and performs maintenance on component mounting unit 45. Line management device 6 can acquire an execution history of maintenance performed on component mounting unit 45 by nozzle maintenance device 78. Further, when regular maintenance of component mounting unit 45 is performed, line management device 6 can acquire a maintenance execution interval and a future execution plan from nozzle maintenance device 78. The maintenance of component supply unit 31 (tape feeder) and component mounting unit 45 (suction nozzle) may be performed by the worker. In this case, the worker may input the execution history of the maintenance to line management device 6 using input device 61, and may further input the execution interval and the execution plan of the maintenance.

As the multiple board work machines constituting board production line 7, solder printing machine 71, print inspection machine 72, component mounter 1, board visual inspector 73, and reflow machine 74 are arranged in order from the upstream side. These board work machines are communicably connected to line management device 6. The line configuration of board production line 7 can be modified in various ways. In addition, line management device 6 may manage multiple board production lines 7.

Line management device 6 receives, substantially in real time, log data LD in which a detailed history of an operation status is recorded from each of the board work machines. A data format of log data LD may be different for each type of board work machine, or may be unified. Log data LD of component mounter 1 includes history information of each of the mounting operations executed multiple times. Log data LD of component mounter 1 may further include conveyance history information related to the conveyance operation of board K and exchange history information related to the exchange operation of a constituent member.

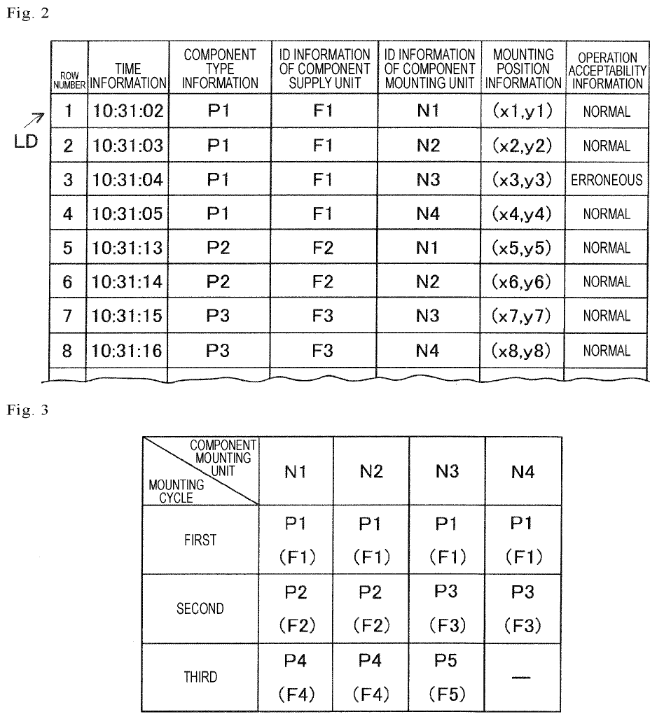

FIG. 2 illustrates an example of log data LD received by line management device 6 from control device 5 of component mounter 1. Each row in FIG. 2 corresponds to one log data LD. Log data LD related to the mounting operation of component mounter 1 has a data format in which six pieces of information are associated with each other. That is, in log data LD, time information, component type information, ID information of component supply unit 31, ID information of component mounting unit 45, mounting position information, and operation acceptability information are associated with each other. Row numbers 1 to 8 are added for convenience in order to distinguish and describe eight pieces of log data LD. In addition, the data format of log data LD of component mounter 1 may be appropriately modified.

The time information indicates the time (hour:minute:second) at which the mounting operation is performed, and is represented by, for example, a timing at which the lifting of component mounting unit 45 that has mounted the component on board K ends. The component type information indicates the type of the component that is a target of the mounting operation. The ID information of component supply unit 31 is information for identifying individual component supply unit 31 that has supplied the component. The ID information of component mounting unit 45 is information for identifying individual component mounting unit 45 that has picked up the component and has mounted the component on board K. The ID information of component supply unit 31 and component mounting unit 45 corresponds to operation condition information indicating a constituent member involved in each of the multiple mounting operations. The mounting position information is information indicating the mounting position on board K on which the component is mounted in an X-Y coordinate system. The operation acceptability information is information indicating the acceptability (normal or erroneous) of an operation result of the mounting operation of the component.

Log data LD in the row number 1 in FIG. 2 is data related to the mounting operation at time 10:31:02. Log data LD indicates that a component of type P1 is supplied from component supply unit 31 with ID information F1 and is mounted at the mounting position (x1,y1) on board K by component mounting unit 45 with ID information N1. Further, log data LD indicates that the operation result of the mounting operation of the component is normal.

In addition, four pieces of log data LD in the row numbers 1 to 4 indicate that four components of type P1 are supplied from component supply unit 31 with ID information F1 and are mounted at four locations on board K by four component mounting units 45 with ID information N1 to N4. Log data LD in the row numbers 1, 2, and 4 indicate that the operation results of the mounting operation to the mounting positions (x1,y1), (x2,y2), and (x4,y4) on board K are normal. In addition, log data LD in the row number 3 indicates that the operation result of the mounting operation to the mounting position (x3,y3) on board K is erroneous. For the mounting position (x3,y3), the mounting cycle for recovery is set, and the mounting operation of the component of type P1 is performed again.

Two pieces of log data LD in the row numbers 5 and 6 indicate that two components of type P2 are supplied from component supply unit 31 with ID information F2 and are mounted at two locations on board K by two component mounting units 45 with ID information N1 and N2. Further, it is indicated that the operation results of the mounting operation to the mounting positions (x5,y5) and (x6,y6) on board K are normal. In addition, two pieces of log data LD in the row numbers 7 and 8 indicate that two components of type P3 are supplied from component supply unit 31 with ID information F3 and are mounted at two locations on board K by two component mounting units 45 with ID information N3 and N4. Further, it is indicated that the operation results of the mounting operation to the mounting positions (x7,y7) and (x8,y8) on board K are normal.

In component mounter 1, an error resulting from a failed mounting operation occurs once in a while. Examples of the error in the mounting operation include the following cases 1) to 7).
1) A case where image data is not acquired by part camera 47
2) A case where image data is not subjected to appropriate image processing
3) A case where it is determined that component mounting unit 45 does not hold a component as a result of the image processing
4) A case where the type of the component is determined to be incorrect as a result of the image processing
5) A case where it is determined that an error in a posture of the component is large and that the mounting operation is impossible as a result of the image processing
6) A case where the component falls from component mounting unit 45 while mounting head 43 is moving from part camera 47 to board K
7) A case where the component is not mounted on board K while being held by component mounting unit 45

In addition to the above, there is an error found from an inspection result of board visual inspector 73. Specifically, board visual inspector 73 determines an error to be present in a case where there is an excessive error in an actual mounting position of the component mounted on board K, a case where there is an excessive error in an orientation (rotation in a horizontal plane) of the component, and a case where the component is mounted at an excessive angle. Then, board visual inspector 73 transmits log data LD including the inspection result of the error to line management device 6. Line management device 6 extracts log data LD of corresponding component mounter 1 based on the mounting position information of the component determined as being erroneous included in log data LD of board visual inspector 73, and rewrites the operation acceptability information from normal to error.

The factors of the errors in the respective cases described above vary, including a case where the factor is component supply unit 31 or component mounting unit 45 (constituent member of component mounter 1) and a case where the factor is mounting job data 52. In addition, constituent members such as mounting head 43, rotary tool 44, and part camera 47 may be the factor of the error. In order to improve efficiency and reduce labor in handling an increase in such errors, error factor identification device 8 is used.

### 3. Configuration and Function of Error Factor Identification Device 8

Next, a configuration and a function of error factor identification device 8 of the embodiment will be described with reference to a functional block diagram in FIG. 1. Error factor identification device 8 is configured as one management functional section of line management device 6. Error factor identification device 8 is not limited to this, and may be configured inside control device 5 of component mounter 1 or may be configured using another computer device. Error factor identification device 8 includes four functional sections, that is, storage section 81, specification section 82, estimation section 83, and notification section 84.

Storage section 81 stores log data LD of component mounter 1 in a memory (not illustrated) or the like. In other words, storage section 81 stores the operation acceptability information and the operation condition information. The operation acceptability information is included in each piece of log data LD illustrated in FIG. 2. The operation condition information is information indicating two or more of multiple constituent members of component mounter 1 and mounting job data 52, which are involved in each of the multiple mounting operations. Information indicating component supply unit 31 and component mounting unit 45 in the operation condition information is included in each piece of log data LD illustrated in FIG. 2. Information indicating mounting head 43, rotary tool 44, and part camera 47 in the operation condition information is acquired from log data LD including the exchange history information of the constituent members of component mounter 1. Mounting job data 52 in the operation condition information is already stored in storage device 51.

Specification section 82 executes specification processing of specifying the factor of the error by using, as a trigger condition, the fact that error occurrence rate EC of the mounting operation exceeds predetermined value E1 in at least one of component mounter 1, any one of the constituent members of component mounter 1, and mounting job data 52. As a supplement, as the population when calculating error occurrence rate EC, one or more combinations of the total number of operations of component mounter 1, the number of operations for each individual component supply unit 31, the number of operations for each individual component mounting unit 45, and the number of operations for each piece of component data of mounting job data 52 can be used. In addition, as predetermined value E1, for example, 0.03% can be set for the total number of operations of component mounter 1, and 0.1% can be set for the number of other operations.

Specification section 82 may collectively calculate, for the multiple constituent members and mounting job data 52, error occurrence rate EC for each individual, each time component mounter 1 performs the mounting operation on a predetermined number of boards K or each time the operation time of component mounter 1 has elapsed by a predetermined time. According to this, it is possible to align time periods of the populations for calculating error occurrence rate EC of each of the multiple constituent members and mounting job data 52, while the sizes of the multiple populations become different.

In addition, specification section 82 may individually calculate, for the multiple constituent members and mounting job data 52, error occurrence rate EC each time, for each individual instance, the number of times of involvement in the mounting operation reaches a predetermined number of times. For example, specification section 82 may individually calculate error occurrence rate EC each time each of multiple component supply units 31 operates 20,000 times, and may individually calculate error occurrence rate EC each time each of multiple component mounting units 45 operates 10,000 times. According to this, it is possible to align the sizes of the populations to a predetermined number of times when calculating error occurrence rate EC of each of the multiple constituent members and mounting job data 52, while the time periods of the multiple populations become different.

Instead of error occurrence rate EC, specification section 82 may execute the specification processing by using, as a trigger condition, the fact that an error occurrence count exceeds a predetermined value. When obtaining the error occurrence count, specification section 82 sets a population in the same manner as when calculating error occurrence rate EC, obtains the error occurrence count within the population, and does not obtain a cumulative occurrence count across populations.

Specification section 82 performs specification processing of comparing error involvement rates ER and specifies the factor of the error, and, specifically, the specification section 82 first calculates two or more of error involvement rate ER of each constituent member and error involvement rate ER of mounting job data 52 based on the operation acceptability information and the operation condition information. Next, under a condition in which the constituent member or mounting job data 52 having higher error involvement rate ER is taken as a first factor and an individual instance of the first factor is specified, specification section 82 determines whether error involvement rate ER is biased according to a difference in an individual instance of another type of constituent member or mounting job data 52 taken as a second factor. When there is no bias, specification section 82 identifies, as the factor of the error, the specified individual instance as the first factor.

When there is bias, the factor of the error is not specified. In this case, specification section 82 further determines whether error involvement rate ER is biased according to a difference in the individual instance of the first factor under a condition in which an individual instance of the second factor in which the error has occurred in a biased manner is specified. When there is no bias, specification section 82 identifies, as the factor of the error, the specified individual instance of the second factor. With the specification processing, the factor of the error is not specified in a case where error involvement rate ER is biased according to the difference in the individual instance of the second factor under the condition in which the individual instance of the first factor is specified and error involvement rate ER is biased according to the difference in the individual instance of the first factor under the condition in which the individual instance of the second factor is specified.

As options of the first factor and the second factor, component supply unit 31 and component mounting unit 45 can be used. In addition, regarding mounting job data 52, multiple pieces of component data can be regarded as different individual instances and can be used as options. Further, mounting head 43 and rotary tool 44 can be used as options when there is log data LD including the exchange history information and multiple individuals are used. In addition, regarding part camera 47, when imaging is performed by switching multiple imaging conditions, the multiple imaging conditions can be regarded as different individual instances and can be used as options. In addition, error involvement rate ER is represented by a ratio in which a total error occurrence count is used as a denominator and an error occurrence count that has occurred in each of multiple individual instances included in the first factor or the second factor is used as a numerator.

In the embodiment, whether error involvement rate ER is biased is determined as follows. That is, specification section 82 determines that error involvement rate ER is biased when error involvement rate ER of one of the multiple individual instances included in the first factor or the second factor is equal to or greater than predetermined involvement rate E2. In addition, specification section 82 determines that error involvement rate ER is not biased when error involvement rate ER of each of the multiple individual instances included in the first factor or the second factor is less than predetermined involvement rate E2. As predetermined involvement rate E2, for example, 80% can be set. The specification processing of specification section 82 will be specifically described in detail with an assumed case in the description of the subsequent operation.

Estimation section 83 uses an estimation logic different from the specification processing of specification section 82, in other words, an estimation logic different from the comparison of error involvement rates ER to estimate the constituent member or mounting job data 52 that is the factor of the error. In the embodiment, estimation section 83 operates only when specification section 82 cannot specify the factor of the error. For example, estimation section 83 operates when specification section 82 cannot specify the factor of the error in the specification processing in which component supply unit 31 and component mounting unit 45 are the first factor and the second factor. Estimation section 83 may operate regardless of the success or failure of the specification processing of specification section 82.

In an example of the estimation logic, estimation section 83 compares last execution times of maintenance performed on component supply unit 31 and component mounting unit 45, which are considered potential factors of the error, and the unit having an older last execution time is regarded as the factor of the error. That is, estimation section 83 performs estimation based on a basic idea (an idea according to an empirical rule) that “a unit having a long elapsed time from maintenance has a high probability of being a factor of an error due to performance deterioration”. In addition, even when mounting head 43 or rotary tool 44 is selected as one of the first factor and the second factor, estimation section 83 can perform the estimation by comparing the last execution times of the maintenance. The estimation logic of estimation section 83 may be modified as described below.

Notification section 84 notifies of the factor of the error specified by specification section 82 and the factor of the error estimated by estimation section 83.

Notification section 84 may perform notification using display device 62 and perform notification to a mobile terminal of the worker through wireless communication as another notification method. In addition, two of component supply unit 31, component mounting unit 45, mounting head 43, and rotary tool 44 may be selected as the first factor and the second factor. In this case, notification section 84 issues a notification to perform maintenance on the factor of the error specified by specification section 82 and the factor of the error estimated by estimation section 83.

Here, the functions of specification section 82 and estimation section 83 cannot be said to be perfect, and it is difficult to rule it out that the factor of the error may be erroneous. That is, even when maintenance is performed on a first one of component supply unit 31 and component mounting unit 45 corresponding to the factor of the error notified from notification section 84 and the unit is reused, there is a case where error occurrence rate EC is not improved to be equal to or less than predetermined value E1. In a case where error occurrence rate EC is not improved, estimation section 83 corrects the estimation such that a second one of component supply unit 31 and component mounting unit 45 being continuously used is regarded as the factor of the error. Then, notification section 84 issues a notification to perform maintenance on the corrected factor of the error. The function of estimation section 83 to correct the factor of the error may be omitted.

### 4. Operation of Error Factor Identification Device 8

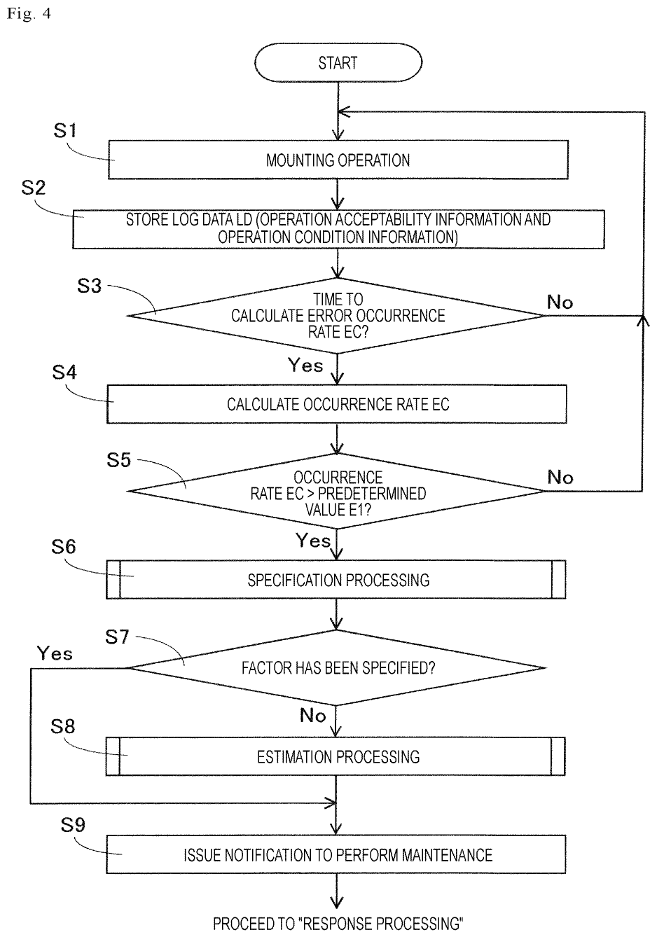

Next, an operation of error factor identification device 8 of the embodiment will be described with reference to FIGS. 3 to 12 with an assumed case. Before describing the operation, the mounting operation on board K is assumed as follows. That is, it is assumed that a total of 11 components are mounted on board K, including four components of type P1, two components of type P2, two components of type P3, two components of type P4, and one component of type P5. In order to respond to this assumption, component mounter 1 executes the mounting operation of three mounting cycles illustrated in FIG. 3.

As illustrated in FIG. 3, component mounter 1 uses first nozzle N1,second nozzle N2, third nozzle N3, and fourth nozzle N4 corresponding to four component mounting units 45 (suction nozzles). In addition, component mounter 1 uses five component supply units 31 (tape feeders) shown in parentheses. Specifically, component mounter 1 uses first feeder F1 that supplies a component of type P1, second feeder F2 that supplies a component of type P2, third feeder F3 that supplies a component of type P3,fourth feeder F4 that supplies a component of type P4, and fifth feeder F5 that supplies a component of type P5.

In a first mounting cycle, component mounter 1 executes a mounting operation of picking up four components of type P1 from first feeder F1 using first nozzle N1 to fourth nozzle N4 and mounting the components on board K. In addition, in a second mounting cycle, component mounter 1 executes a mounting operation of picking up two components of type P2 from second feeder F2 using first nozzle N1 and second nozzle N2 and picking up two components of type P3 from third feeder F3 using third nozzle N3 and fourth nozzle N4. Further, in a third mounting cycle, component mounter 1 executes a mounting operation of picking up two components of type P4 from fourth feeder F4 using first nozzle N1 and second nozzle N2 and picking up one component of type P5 from fifth feeder F5 using third nozzle N3. Component mounter 1 does not use fourth nozzle N4 in the third mounting cycle.

Further, it is assumed that specification section 82 selects component supply unit 31 and component mounting unit 45 as the first factor and the second factor. In addition, it is assumed that specification section 82 collectively calculates error occurrence rate EC for each individual component supply unit 31 and each individual component mounting unit 45, each time component mounter 1 performs the mounting operation on 5000 boards K. In addition, it is assumed that predetermined value E1 is set to 0.1% as a trigger condition for specification section 82 to execute the specification processing. In addition, it is assumed that predetermined involvement rate E2 for determining whether error involvement rate ER is biased is set to 80%.

Based on the above assumption, the operation of error factor identification device 8 will be described with reference to an operation flow illustrated in FIG. 4. In step S1 of FIG. 4, component mounter 1 sequentially executes the mounting operations of the first to third mounting cycles, and then switches board K and continues the mounting operation. In next step S2, storage section 81 acquires and stores log data LD related to each of the mounting operations of component mounter 1. As described above, log data LD includes the operation acceptability information and the operation condition information for each mounting operation. The execution frequency of the storage processing may be each time one mounting operation is completed, each time one mounting cycle (three to four mounting operations) is completed, or each time 11 mounting operations on one board K are completed.

In next step S3, specification section 82 determines whether the calculation time of error occurrence rate EC has arrived, and branches the operation flow. The calculation time has not arrived when the mounting operations on 5000 boards K have not been completed after the start of production of board K or after the previous calculation time. In this case, specification section 82 returns the operation flow to step S1. Then, the operation loop of steps S1 to S3 is repeated until the calculation time arrives, and log data LD is accumulated. When the calculation time has arrived in step S3, specification section 82 advances the operation flow to step S4.

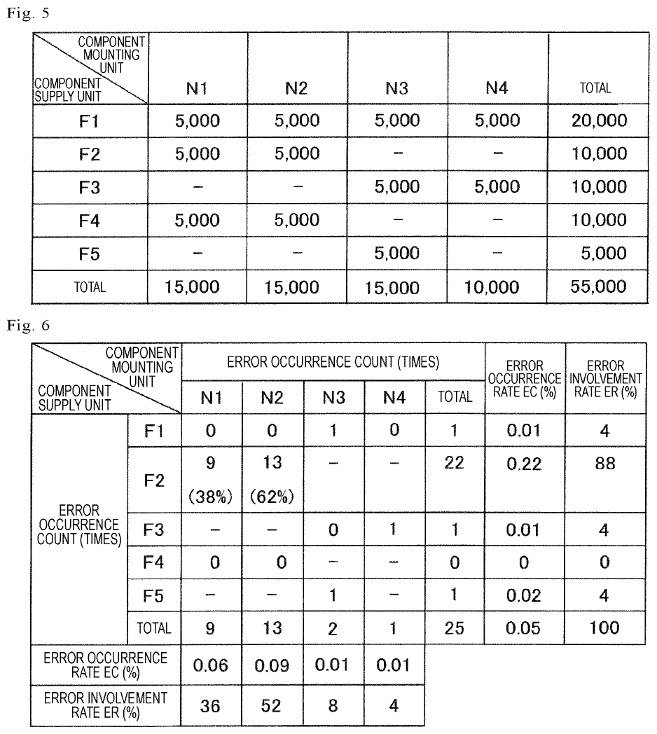

In step S4, specification section 82 collectively calculates error occurrence rate EC for each individual component supply unit 31 and each individual component mounting unit 45. FIG. 5 illustrates the number of operations as a population for calculating error occurrence rate EC. As illustrated in the drawing, the total number of mounting operations of component mounter 1 is 55,000 (=5000 boards×11 operations). The number of operations for each individual component supply unit 31 is 20,000 for the first feeder, 10,000 for second feeder F2, third feeder F3, and fourth feeder F4, and 5,000 for fifth feeder F5. The number of operations for each individual component mounting unit 45 is 15,000 for first nozzle N1, second nozzle N2, and third nozzle N3, and 10,000 for fourth nozzle N4.

Here, in a first example illustrated in FIG. 6, it is assumed that a total of 25 errors occur in component mounter 1. The details of the error occurrence count for each individual component supply unit 31 are such that the first feeder has one occurrence, second feeder F2 has 22 occurrences, third feeder F3 has one occurrence, fourth feeder F4 has zero occurrences, and fifth feeder F5 has one occurrence. Specification section 82 calculates error occurrence rate EC by dividing these occurrence counts by the number of operations of the population illustrated in FIG. 5. Specific error occurrence rates EC are 0.01% for the first feeder, 0.22% for second feeder F2, 0.01% for third feeder F3, 0% for fourth feeder F4, and 0.02% for fifth feeder F5 (values less than 0.01% are rounded).

The details of the error occurrence count for each individual component mounting unit 45 are such that first nozzle N1 has nine occurrences, second nozzle N2 has 13 occurrences, third nozzle N3 has two occurrences, and fourth nozzle N4 has one occurrence. Specification section 82 calculates error occurrence rate EC by dividing these occurrence counts by the number of operations of the population illustrated in FIG. 5. Specific error occurrence rates EC are 0.06% for first nozzle N1, 0.09% for second nozzle N2, 0.01% for third nozzle N3, and 0.01% for fourth nozzle N4.

In next step S5, specification section 82 determines the presence or absence of error occurrence rate EC exceeding predetermined value E1 (=0.1%), and branches the operation flow. When the error occurrence count is small and there is no error occurrence rate EC exceeding predetermined value E1, specification section 82 returns the operation flow to step S1. Thereafter, steps S1 to S5 are repeated. In the first example, error occurrence rate EC of second feeder F2 is 0.22% and exceeds predetermined value E1, and specification section 82 advances the operation flow to step S6. In addition, it is assumed that predetermined value E1 may be set to 0.03% for the total number of operations of component mounter 1 as a trigger condition for specification section 82 to execute the specification processing. In this case, since error occurrence rate EC of component mounter 1 is 0.05% (=25/55,000×100) and exceeds predetermined value E1, specification section 82 advances the operation flow to step S6.

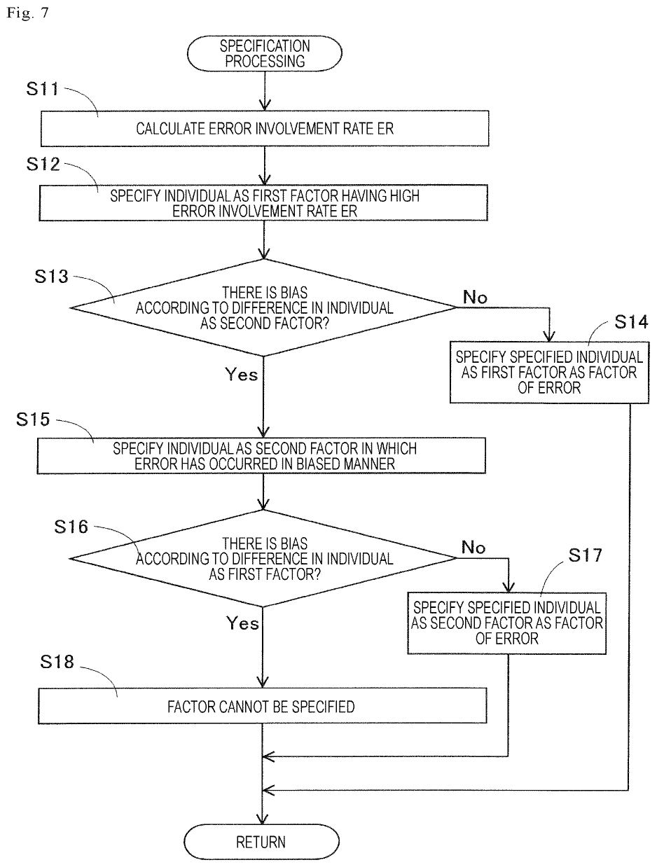

In step S6, specification section 82 executes specification processing for specifying the factor of the error. Here, when second feeder F2 having the largest error occurrence count is simply identified as the factor of the error, there is a possibility of being erroneous. Therefore, specification section 82 executes specification processing illustrated in a sub-operation flow of FIG. 7. In step S11 of FIG. 7, specification section 82 calculates error involvement rate ER for each individual component supply unit 31 and each individual component mounting unit 45. As illustrated in FIG. 6, in the first example, error involvement rate ER for each individual component supply unit 31 is 4% for the first feeder, 88% (=22/25×100) for second feeder F2, 4% for third feeder F3, 0% for fourth feeder F4, and 4% for fifth feeder F5. In addition, error involvement rate ER for each individual component mounting unit 45 is 36% for first nozzle N1, 52% (=13/25×100) for second nozzle N2, 8% for third nozzle N3, and 4% for fourth nozzle N4.

In next step S12, specification section 82 specifies an individual as the first factor having high error involvement rate ER. In the first example, specification section 82 selects component supply unit 31 as the first factor, selects component mounting unit 45 as the second factor, and specifies second feeder F2 having high error involvement rate ER of 88% as the first factor. In next step S13, specification section 82 determines the presence or absence of the bias according to a difference in the individual instance of the second factor under a condition in which second feeder F2 is specified.

Under the condition in which second feeder F2 is specified, the total error occurrence count is 22, and the details thereof are such that first nozzle N1 has nine occurrences and second nozzle N2 has 13 occurrences.

Specification section 82 calculates error involvement rate ER for each individual instance of the second factor under the condition in which second feeder F2 is specified. As a result, as shown in parentheses in FIG. 6, error involvement rate ER of first nozzle N1 as the second factor is 38% (=9/22×100), and error involvement rate ER of second nozzle N2 is 62% (=13/22×100). Both error involvement rates ER are less than predetermined involvement rate E2 (=80%), and there is no bias according to the difference in the individual as the second factor. Therefore, the sub-operation flow branches to step S14.

In step S14, specification section 82 specifies the specified individual as the first factor, that is, second feeder F2 as the factor of the error. As a supplement, second feeder F2 having the largest error occurrence count is naturally highly likely to be the factor of the error. However, it cannot be excluded that one of component mounting units 45 used in combination is the factor of the error. Here, it is found that the errors are not biased to one of first nozzle N1 and second nozzle N2, but occur in both of them. It is extremely rare for first nozzle N1 and second nozzle N2 to simultaneously experience deterioration in performance and cause an error. Therefore, specification section 82 can specify that the occurrence of the error is due to performance deterioration of second feeder F2, and there is almost no possibility of the specification result being erroneous.

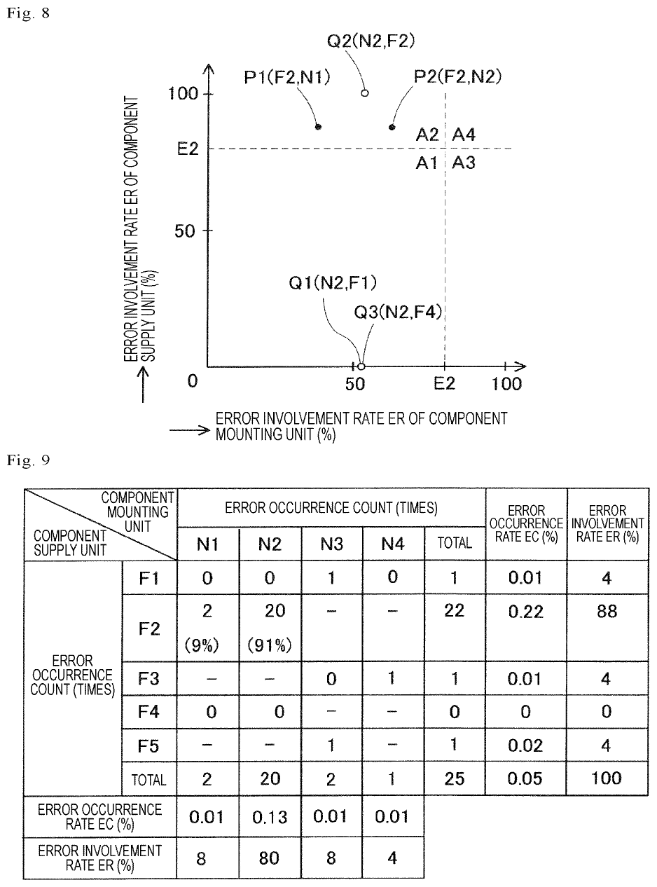

The processing contents of the specific processing are schematically illustrated in an error factor specification diagram of FIG. 8. In the error factor specification diagram, a vertical axis represents error involvement rate ER of component supply unit 31, and a horizontal axis represents error involvement rate ER of component mounting unit 45. The error factor specification diagram is divided into four regions by predetermined involvement rate E2 (=80%) indicated by a broken line. Specifically, a region in which error involvement rates ER of component supply unit 31 and component mounting unit 45 are both less than predetermined involvement rate E2 is first region A1. A region in which error involvement rate ER of component supply unit 31 is equal to or greater than predetermined involvement rate E2 and error involvement rate ER of component mounting unit 45 is less than predetermined involvement rate E2 is second region A2. A region in which error involvement rate ER of component supply unit 31 is less than predetermined involvement rate E2 and error involvement rate ER of component mounting unit 45 is equal to or greater than predetermined involvement rate E2 is third region A3. A region in which error involvement rates ER of component supply unit 31 and component mounting unit 45 are both equal to or greater than predetermined involvement rate E2 is fourth region A4.

Specification section 82 calculates error involvement rate ER of the first nozzle N1 and error involvement rate ER of second nozzle N2 under the condition in which second feeder F2 is specified as described above. The calculation results are plotted as P1(F2,N1) and P2(F2,N2) in the error factor specification diagram. For example, P1(F2,N1) is plotted at an intersection of 88% of error involvement rate ER of second feeder F2 and 38% of error involvement rate ER of first nozzle N1 under the condition in which second feeder F2 is specified. As illustrated in the drawing, when plots such as P1(F2,N1) and P2(F2,N2), which indicate the processing contents of specification section 82, are included in second region A2, specification section 82 can specify one of component supply units 31 as the factor of the error. In consideration of the duality between component supply unit 31 and component mounting unit 45, when the plots indicating the processing contents of specification section 82 are included in third region A3, specification section 82 can specify one of component mounting units 45 as the factor of the error.

Next, as an application example, a case where the first factor and the second factor are switched and selected will be described. In step S12, specification section 82 may select component mounting unit 45 as the first factor, select component supply unit 31 as the second factor, and specify second nozzle N2 having high error involvement rate ER of 52% as the first factor. Then, in next step S13, specification section 82 determines the presence or absence of the bias according to a difference in the individual as the second factor under a condition in which second nozzle N2 is specified. Under the condition that second nozzle N2 is specified, the total error occurrence count is 13. The error occurrence count of second feeder F2 as the second factor is 13 with error involvement rate ER of 100%, and the error occurrence count of first feeder F1 and fourth feeder F4 is 0 with error involvement rate ER of 0%. That is, error involvement rate ER of second feeder F2 is equal to or greater than predetermined involvement rate E2 and is biased. Therefore, the sub-operation flow branches to step S15. The processing contents are plotted as Q1(N2,F1), Q2(N2,F2), and Q3(N2,F4) in the error factor specification diagram of FIG. 8.

In step S15, specification section 82 specifies second feeder F2 that is an individual as the second factor in which the error has occurred in a biased manner. In next step S16, specification section 82 determines the presence or absence of the bias according to a difference in the individual as the first factor under a condition in which second feeder F2 is specified. Under the condition that second feeder F2 is specified, the total error occurrence count is 22. Error involvement rate ER of first nozzle N1 as the first factor is 38%, and error involvement rate ER of second nozzle N2 is 62%. Therefore, error involvement rate ER is not biased, and the sub-operation flow branches to step S17.

In step S17, specification section 82 specifies the specified individual as the second factor, that is, second feeder F2 as the factor of the error. As described above, specification section 82 can obtain the same specification result as that of the first example even when the specification processing in which the first factor and the second factor are switched in the application example is executed. By executing step S14 or step S17, the sub-operation flow of the specification processing ends.

Next, specification processing of specification section 82 when a second example illustrated in FIG. 9 is targeted will be described. In the second example, it is assumed that a total of 25 errors occur in component mounter 1. The details of the error occurrence count for each individual component supply unit 31 are such that the first feeder has one occurrence, second feeder F2 has 22 occurrences, third feeder F3 has one occurrence, fourth feeder F4 has zero occurrences, and fifth feeder F5 has one occurrence. Therefore, error occurrence rate EC for each individual component supply unit 31 calculated by specification section 82 in step S4 is 0.01% for the first feeder, 0.22% for second feeder F2, 0.01% for third feeder F3, 0% for fourth feeder F4, and 0.02% for fifth feeder F5.

In addition, the details of the error occurrence count for each individual component mounting unit 45 are such that first nozzle N1 has two occurrences, second nozzle N2 has 20 occurrences, third nozzle N3 has two occurrences, and fourth nozzle N4 has one occurrence. Therefore, error occurrence rate EC for each individual component mounting unit 45 calculated by specification section 82 is 0.01% for first nozzle N1, 0.13% for second nozzle N2, 0.01% for third nozzle N3, and 0.01% for fourth nozzle N4.

In next step S5, since error occurrence rate EC of second feeder F2 is 0.22% and is equal to or greater than predetermined value E1, specification section 82 advances the operation flow to step S6. In step S11 of FIG. 7, which corresponds to the specification processing of step S6, error involvement rate ER for each individual component supply unit 31 calculated by specification section 82 is 4% for the first feeder, 88% (=22/25×100) for second feeder F2, 4% for third feeder F3, 0% for fourth feeder F4, and 4% for fifth feeder F5. In addition, error involvement rate ER for each individual component mounting unit 45 is 8% for first nozzle N1, 80% (=20/25×100) for second nozzle N2, 8% for third nozzle N3, and 4% for fourth nozzle N4.

In next step S12, specification section 82 selects component supply unit 31 as the first factor, selects component mounting unit 45 as the second factor, and specifies second feeder F2 having high error involvement rate ER of 88% as the first factor. In next step S13, specification section 82 calculates error involvement rate ER of first nozzle N1 as the second factor as 9% (=2/22×100) and error involvement rate ER of second nozzle N2 as 91% (=20/22×100) under the condition that second feeder F2 is specified. Since error involvement rate ER of second nozzle N2 is biased to be equal to or greater than predetermined involvement rate E2 (=80%), specification section 82 advances the sub-operation flow to step S15.

In step S15, specification section 82 specifies second nozzle N2 that is an individual instance of the second factor in which the error has occurred in a biased manner. In next step S16, specification section 82 calculates error involvement rate ER of second feeder F2 as the first factor as 100% (=22/22×100) and error involvement rates ER of first feeder F1 and fourth feeder F4 as 0% under the condition that second nozzle N2 is specified. Therefore, error involvement rate ER of second feeder F2 is biased to be equal to or greater than predetermined involvement rate E2, and specification section 82 advances the sub-operation flow to step S18. In step S18, specification section 82 determines that the factor of the error cannot be specified, and the sub-operation flow ends.

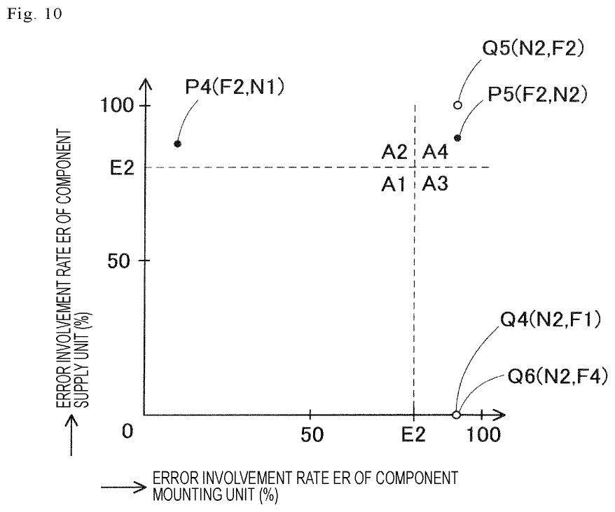

The processing contents of the specific processing in the second example are schematically illustrated in an error factor specification diagram of FIG. 10. Specifically, the processing contents of steps S12 and S13 by specification section 82 are plotted as P4(F2,N1) and P5(F2,N2) in the error factor specification diagram. In addition, the processing contents of step S16 by specification section 82 are plotted as Q4(N2,F1), Q5(N2,F2), and Q6(N2,F4) in the error factor specification diagram. As illustrated in the drawing, when plots such as P5(F2,N2) and Q5(N2,F2), which indicate the processing contents of specification section 82, are included in fourth region A4, specification section 82 cannot specify the factor of the error.

In addition, there is a case where a relatively large number of errors are distributed to multiple component supply units 31 and to multiple component mounting units 45. In this case, plots indicating the processing contents of specification section 82 are included in first region A1, and specification section 82 cannot specify the factor of the error. Such a case occurs, for example, when multiple units among multiple component supply units 31 and multiple component mounting units 45 deteriorate in performance simultaneously and cause an error. In the illustrated case, specification section 82 cannot specify the factor of the error, but estimation section 83 can estimate a first unit that is a factor of the error. After the first unit is subjected to maintenance and reused or a spare unit is used instead of the first unit, specification section 82 can specify a second unit that is a factor of the error in the next specification processing.

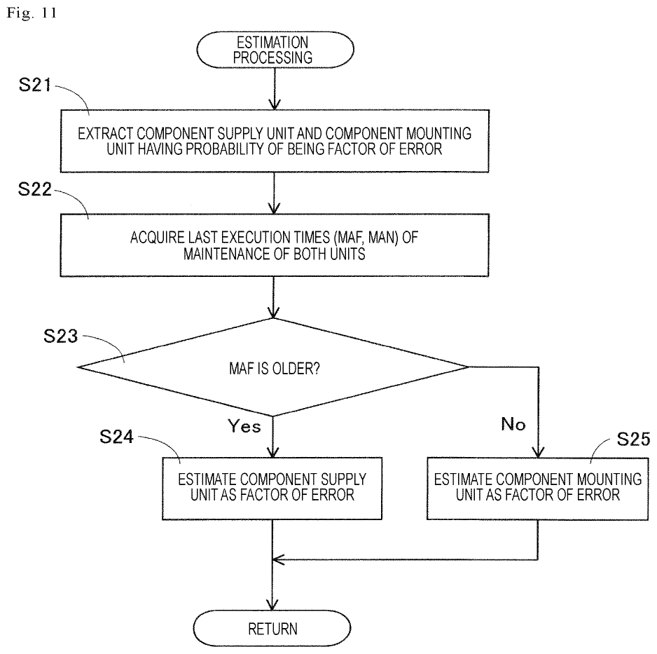

Returning to step S7 of FIG. 4, estimation section 83 branches the operation flow depending on whether specification section 82 has specified the factor of the error. When specification section 82 has been able to specify the factor of the error, estimation section 83 skips step S8 and advances the operation flow to step S9. On the other hand, when specification section 82 has not been able to specify the factor of the error, estimation section 83 executes estimation processing illustrated in the sub-operation flow of FIG. 11 in step S8.

In step S21 of FIG. 11, estimation section 83 extracts component supply unit 31 and component mounting unit 45 having a probability of being the factor of the error. For example, in the second example, estimation section 83 extracts second feeder F2 and second nozzle N2 in which the error has occurred in a biased manner. In next step S22, estimation section 83 acquires last execution times of maintenance on both units. That is, estimation section 83 acquires last execution time MAF of the maintenance on second feeder F2 from feeder maintenance device 77. In addition, estimation section 83 acquires last execution time MAN of maintenance on second nozzle N2 from nozzle maintenance device 78.

In next step S23, estimation section 83 advances the sub-operation flow to step S24 when last implementation time MAF of second feeder F2 is older than last execution time MAN of second nozzle N2; otherwise, advances the sub-operation flow to step S25. In step S24, estimation section 83 estimates that second feeder F2 (component supply unit 31) is the factor of the error. In addition, in step S25, estimation section 83 estimates that second nozzle N2 (component mounting unit 45) is the factor of the error. That is, the estimation section estimates the unit having the older last execution time of the maintenance as the factor of the error. Thus, the sub-operation flow of the estimation processing ends.

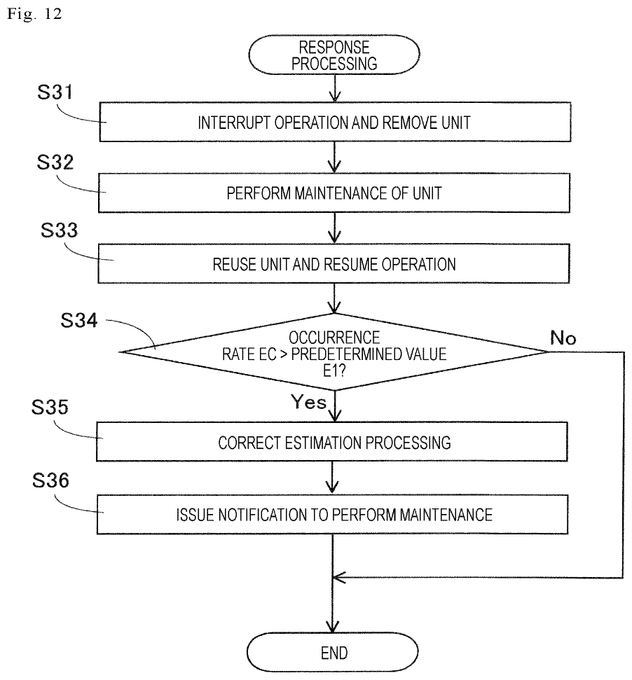

Returning to step S9 of FIG. 4, notification section 84 issues a notification to perform maintenance on the factor of the error specified by specification section 82. In addition, when specification section 82 has not been able to specify the factor of the error, notification section 84 issues a notification to perform maintenance on the factor of the error estimated by estimation section 83. Then, the operation flow illustrated in FIG. 4 ends, and error factor identification device 8 proceeds to response processing illustrated in FIG. 12. In the response processing, a case where notification section 84 issues a notification to perform maintenance on second feeder F2 (first one) indicated by the estimation result of estimation section 83 out of second feeder F2 (first one) and second nozzle N2 (second one) in which the error has occurred in a biased manner will be described as an example.

In step S31 of the response processing illustrated in FIG. 12, the worker interrupts the operation of component mounter 1 and removes second feeder F2 for which maintenance has been notified of. In next step S32, the worker carries second feeder F2 into feeder maintenance device 77 and performs maintenance. In next step S33, the worker mounts second feeder F2 for which the maintenance has been completed on component mounter 1, reuses second feeder F2, and resumes the operation of component mounter 1. In next step S34, steps S1 to S4 of FIG. 4 are executed, and specification section 82 calculates error occurrence rate EC for each individual second feeder F2. Estimation section 83 determines whether calculated error occurrence rate EC is improved to be equal to or less than predetermined value E1 (=0.1%), and branches the operation flow.

In many cases, the factor of the error is correctly specified, appropriate maintenance is performed, and error occurrence rate EC is improved. Therefore, component mounter 1 can continue the stable mounting operation. Thus, the operation flow of the response processing ends. On the other hand, in step S35 in a case where error occurrence rate EC is not improved, estimation section 83 corrects the estimation such that second nozzle N2 (second one) being continuously used is regarded as the factor of the error. In next step S36, notification section 84 issues a notification to perform maintenance on second nozzle N2 which is the corrected factor of the error. Then, the operation flow of the response processing ends.

The worker removes second nozzle N2 for which maintenance has been notified of from component mounter 1 and causes nozzle maintenance device 78 to perform the maintenance. Further, the worker mounts second nozzle N2 for which the maintenance has been completed on component mounter 1, reuses second nozzle N2, and resumes the operation of component mounter 1. With this, since the maintenance is performed on both second feeder F2 and second nozzle N2, which are considered potential factors of the error, the occurrence status of the error is improved in most cases.

In an alternative method of step S33, the worker may mount spare sixth feeder F6 in place of second feeder F2 for which the maintenance has been notified of on component mounter 1, and resume the operation of component mounter 1. In this case, when the factor of the error is second feeder F2, error occurrence rate EC is improved, and the operation flow proceeds from step S34 to the end. When the factor of the error is other than second feeder F2, error occurrence rate EC is not improved, and the operation flow proceeds from step S34 to step S35. In step S35, estimation section 83 corrects the estimation such that second nozzle N2 being continuously used is regarded as the factor of the error. In next step S36, notification section 84 issues a notification to perform maintenance on second nozzle N2. Then, the operation flow of the response processing ends.

### 5. Modified Form of Estimation Processing of Estimation Section 83

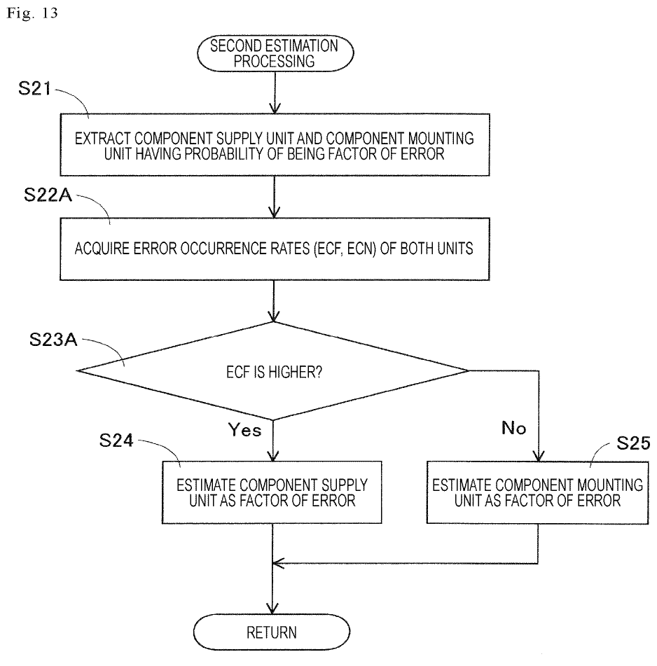

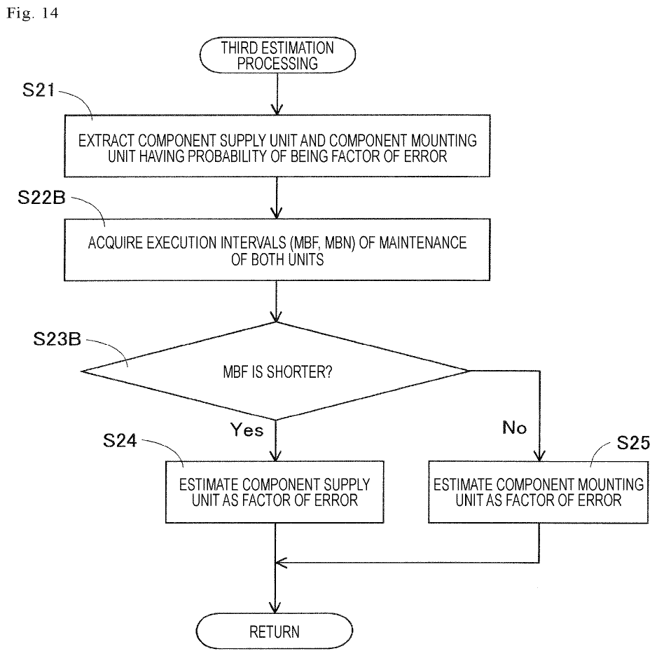

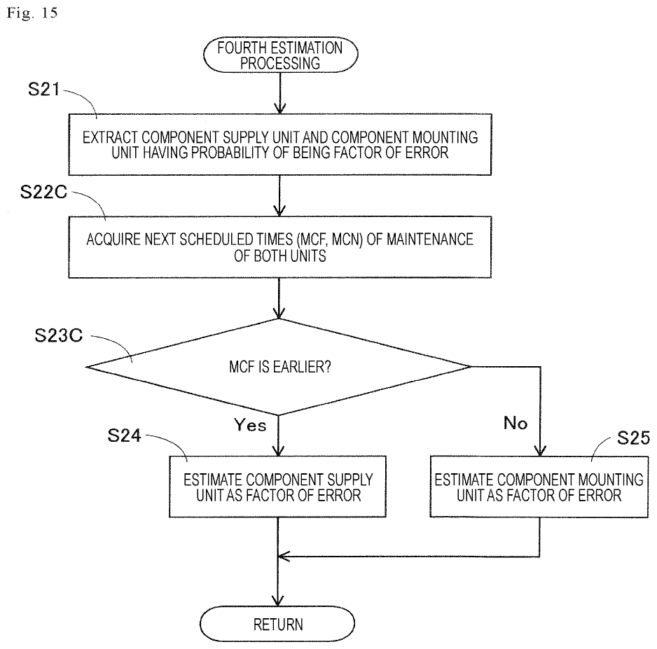

The estimation processing of estimation section 83 can be modified into second estimation processing illustrated in FIG. 13, third estimation processing illustrated in FIG. 14, and fourth estimation processing illustrated in FIG. 15. In the second estimation processing to the fourth estimation processing, step S21, step S24, and step S25 are the same as those in the estimation processing described with reference to FIG. 11, and the processing contents of step S22 and step S23 are changed.

In step S22A of the second estimation processing illustrated in FIG. 13, estimation section 83 acquires error occurrence rate ECF of second feeder F2 (component supply unit 31) and error occurrence rate ECN of second nozzle N2 (component mounting unit 45) from specification section 82. In next step S23A, estimation section 83 advances the sub-operation flow to step S24 when error occurrence rate ECF of second feeder F2 is higher than error occurrence rate ECN of second nozzle N2; otherwise, advances the sub-operation flow to step S25. That is, estimation section 83 performs estimation based on a basic idea that “a unit having a high error occurrence rate has a high probability of being a factor of an error”. Estimation section 83 may acquire the error occurrence counts from specification section 82 instead of the error occurrence rates (ECF, ECN), compare the error occurrence counts, and advance the sub-operation flow to step S24 or step S25.

In step S22B of the third estimation processing illustrated in FIG. 14, estimation section 83 acquires execution interval MBF of the maintenance of second feeder F2 (component supply unit 31) from feeder maintenance device 77. In addition, estimation section 83 acquires execution interval MBN of the maintenance of second nozzle N2 (component mounting unit 45) from nozzle maintenance device 78. In next step S23B, estimation section 83 advances the sub-operation flow to step S24 when execution interval MBF of the maintenance of second feeder F2 is shorter than execution interval MBN of the maintenance of second nozzle N2; otherwise, advances the sub-operation flow to step S25. That is, estimation section 83 performs estimation based on a basic idea that “maintenance with a short execution interval is recommended for a unit that is prone to performance deterioration and has a high probability of being a factor of an error”.

In step S22C of the fourth estimation processing illustrated in FIG. 15, estimation section 83 acquires next scheduled time MCF of the maintenance of second feeder F2 (component supply unit 31) from feeder maintenance device 77. In addition, estimation section 83 acquires next scheduled time MCN of the maintenance of second nozzle N2 (component mounting unit 45) from nozzle maintenance device 78. In next step S23C, estimation section 83 advances the sub-operation flow to step S24 when next scheduled time MCF of the maintenance of second feeder F2 is earlier than next scheduled time MCN of the maintenance of second nozzle N2; otherwise, advances the sub-operation flow to step S25. That is, estimation section 83 performs estimation based on a basic idea that “a unit in which an elapsed time from previous maintenance becomes long and a next scheduled time approaches has a high probability of being a factor of an error due to performance deterioration”.

With error factor identification device 8 of the embodiment, storage section 81 stores the operation acceptability information and the operation condition information of each of the mounting operations executed multiple times in component mounter 1. In addition, specification section 82 specifies the factor of the error by comparing two or more error involvement rates ER when error occurrence rate EC in the mounting operation exceeds predetermined value E1, and estimation section 83 estimates the factor of the error by using an estimation logic different from that of specification section 82. Here, since “specify” and “estimate” correspond to one form of “identify”, even in a case where specification section 82 cannot identify (specify) the factor of the error, estimation section 83 can identify (estimate) the factor of the error and reduce cases where the factor of the error is not identified.

### 6. Other Applications and Modifications of Embodiment

Note that error factor identification device 8 of the embodiment functions in the same manner for actual operation situations other than the assumed first example and second example, and also functions in the same manner under conditions different from the assumed conditions. For example, the number of components mounted on board K and the number of component supply units 31 and component mounting units 45 used are generally larger than those in the assumed example. In addition, the population for calculating error occurrence rate EC does not have to be 5000 boards K. Further, predetermined value E1 and predetermined involvement rate E2 may be set to values different from those in the embodiment.

In a form in which estimation section 83 operates regardless of the success or failure of the specification processing of specification section 82, the specification result of specification section 82 and the estimation result of estimation section 83 do not always match. In a case where they match, notification section 84 needs only to notify of the matched factor of the error. In a case where they do not match, notification section 84 preferentially notifies of the factor of the error specified by specification section 82, or notifies of the two factors that do not match. In addition, the processing contents of the specification processing of specification section 82 can be modified as appropriate, and estimation section 83 is required to use an estimation logic different from the modified specification processing of specification section 82. In addition, various applications and modifications can be made to the embodiments and the modified forms.

### REFERENCE SIGNS LIST

1: Component mounter, 2: Board conveyance device, 3: Component supply device, 31: Component supply unit, 4: Component transfer device, 43: Mounting head, 45: Component mounting unit, 47: Part camera, 5: Control device, 52: Mounting job data, 6: Line management device, 7: Board production line, 73: Board visual inspector, 77: Feeder maintenance device, 78: Nozzle maintenance device, 8: Error factor identification device, 81: Storage section, 82: Specification section, 83: Estimation section, 84: Notification section, LD: Log data, EC, ECF, ECN: (Error) occurrence rate, ER: Error involvement rate, E1: Predetermined value, E2: Predetermined involvement rate, MAF, MAN: Last execution time, MBF, MBN: Execution interval, MCF, MCN: Next scheduled time

1. An error factor identification device comprising:
a storage section configured to store operation acceptability information indicating acceptability of an operation result of each of mounting operations executed multiple times in a component mounter and operation condition information indicating two or more of multiple constituent members of the component mounter and mounting job data, which are involved in each of the multiple mounting operations;
a specification section configured to, when an occurrence rate or an occurrence count of an error in the mounting operation exceeds a predetermined value in at least one of the component mounter, the constituent member, and the mounting job data, specify the constituent member or the mounting job data that is a factor of the error by comparing two or more of an error involvement rate of each constituent member and an error involvement rate of the mounting job data calculated based on the operation acceptability information and the operation condition information, and
an estimation section configured to estimate the constituent member or the mounting job data that is the factor of the error by using a predetermined estimation logic different from the comparison of the error involvement rates.

2. The error factor identification device according to claim 1, wherein, under a condition in which the constituent member or the mounting job data having a high error involvement rate is taken as a first factor and an individual instance of the first factor is specified, in a case where another type of the constituent member or the mounting job data is taken as a second factor and the error involvement rate is not biased according to a difference in an individual instance of the second factor, the specification section identifies, as the factor of the error, the specified individual instance of the first factor.

3. The error factor identification device according to claim 2, wherein, in a case where the error involvement rate is biased according to the difference in the individual instance of the second factor under the condition in which the individual instance of the first factor is specified, when the error involvement rate is not biased according to a difference in the individual instance of the first factor under a condition in which an individual instance of the second factor in which the error has occurred in a biased manner is specified, the specification section identifies, as the factor of the error, the specified individual instance of the second factor.

4. The error factor identification device according to claim 2, wherein the specification section determines that the error involvement rate is biased when the error involvement rate of one of multiple individuals instances included in the first factor or the second factor is equal to or greater than a predetermined involvement rate.

5. The error factor identification device according to claim 1,
wherein the multiple constituent members include a component supply unit configured to supply a component in the mounting operation and a component mounting unit configured to pick up the component from the component supply unit and mount the component on a board, and
the estimation section uses the estimation logic in which, by comparing last execution times of maintenance performed on the component supply unit and the component mounting unit, which are considered potential factors of the error, the unit having an older last execution time is regarded as the factor of the error.

6. The error factor identification device according to claim 1,
wherein the multiple constituent members include a component supply unit configured to supply a component in the mounting operation and a component mounting unit configured to pick up the component from the component supply unit and mount the component on a board, and
the estimation section uses the estimation logic in which, by comparing the occurrence rate or the occurrence count of the error between the component supply unit and the component mounting unit, which are considered potential factors of the error, the unit having a higher occurrence rate or a higher occurrence count is regarded as the factor of the error.

7. The error factor identification device according to claim 1,
wherein the multiple constituent members include a component supply unit configured to supply a component in the mounting operation and be subjected to regular maintenance and a component mounting unit configured to pick up the component from the component supply unit, mount the component on a board, and be subjected to regular maintenance, and
the estimation section uses the estimation logic in which, by comparing execution intervals of the maintenance of the component supply unit and the component mounting unit, which are considered potential factors of the error, the unit having a shorter execution interval is regarded as the factor of the error.

8. The error factor identification device according to claim 1,
wherein the multiple constituent members include a component supply unit configured to supply a component in the mounting operation and be subjected to regular maintenance and a component mounting unit configured to pick up the component from the component supply unit, mount the component on a board, and be subjected to regular maintenance, and
the estimation section uses the estimation logic in which, by comparing next scheduled times of the maintenance of the component supply unit and the component mounting unit, which are considered potential factors of the error, the unit having an earlier next scheduled time is regarded as the factor of the error.

9. The error factor identification device according to claim 1, wherein the estimation section operates only when the specification section is not able to specify the factor of the error.

10. The error factor identification device according to claim 1, further comprising:
a notification section configured to notify of the factor of the error identified by the specification section and the factor of the error estimated by the estimation section.

11. The error factor identification device according to claim 5, further comprising:
a notification section configured to issue a notification to perform maintenance on the factor of the error identified by the specification section and the factor of the error estimated by the estimation section.

12. The error factor identification device according to claim 11,
wherein the estimation section uses the estimation logic in which, in a case where the occurrence rate or the occurrence count of the error is not improved to be equal to or less than the predetermined value even when the maintenance is performed on a first one of the component supply unit and the component mounting unit corresponding to the factor of the error notified from the notification section and the unit is reused, a second one of the component supply unit and the component mounting unit is corrected to be the factor of the error, and
the notification section issues a notification to perform the maintenance of the corrected factor of the error.

13. The error factor identification device according to claim 1, wherein the specification section collectively obtains, for two or more of the multiple constituent members and the mounting job data, the occurrence rate or the occurrence count of the error for each individual instance, each time the component mounter performs the mounting operation on a predetermined number of boards or each time an operation time of the component mounter has elapsed by a predetermined time.

14. The error factor identification device according to claim 1, wherein the specification section individually obtains, for two or more of the multiple constituent members and the mounting job data, the occurrence rate or the occurrence count of the error each time, for each individual instance, the number of times of involvement in the mounting operation reaches a predetermined number of times.

15. The error factor identification device according to claim 1, wherein the multiple constituent members include one or more of a component supply unit configured to supply a component in the mounting operation, a component mounting unit configured to pick up the component from the component supply unit and mount the component on a board, a mounting head configured to hold the component mounting unit and move between the component supply unit and the board, and a part camera configured to image the component picked up by the component mounting unit.
